(19) United States
(12) Patent Application Publication
(10) Pub. No.: US 2026/0282906 A1
(43) Pub. Date: Sep. 17, 2026

(54) SEMICONDUCTOR PACKAGE AND METHOD FOR FORMING THE SAME

(71) Applicant: STATS ChipPAC Management Pte. Ltd., Singapore (SG)

(72) Inventors: ChangOh KIM, Incheon (KR); JinHee JUNG, Incheon (KR); HeeSoo LEE, Incheon (KR)

(21) Appl. No.: 19/557,176

(22) Filed: Mar. 5, 2026

(30) Foreign Application Priority Data
Mar. 12, 2025 (CN) 202510292291.4

(51) Int. Cl. H10W 40/20; H10W 72/00; H10W 72/30; H10W 74/15; H10W 90/00; H10W 90/28

(52) U.S. Cl. CPC H10W 40/242; H10W 40/233; H10W 72/07336; H10W 72/07338; H10W 72/322; H10W 90/28; H10W 90/737; H10W 90/792; H10W 74/15; H10W 90/724

(57) ABSTRACT

A semiconductor package and a method for forming the same are provided. The method includes: providing a substrate; providing a semiconductor die stack including a first semiconductor die; mounting the semiconductor die stack on an upper surface of the substrate; forming a first barrier wall on the upper surface of the substrate, wherein the first barrier wall covers a lateral surface of the first semiconductor die and protrudes from an upper surface of the first semiconductor die; dispensing a first fluid material on the upper surface of the first semiconductor die, wherein the first barrier wall prevents the first fluid material from flowing across it; and curing the first fluid material to form a back side metallization (BSM) layer.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. In order to meet the needs of consumers, more and more electronic components are tightly integrated within a single device or package. Yet, due to the tight integration, heat generated from an electronic component may be blocked by other electronic components within the same package, rendering unsatisfactory heat dissipation, and thus the performance of the semiconductor package may be impacted.

Therefore, a need exists for a semiconductor package with improved heat dissipation capacity.

### SUMMARY OF THE INVENTION

An objective of the present application is to provide a method for making a semiconductor package with an improved heat dissipation capacity.

According to an aspect of the present application, a method for forming a semiconductor package is provided. The method may include: providing a substrate; providing a semiconductor die stack including a first semiconductor die; mounting the semiconductor die stack on an upper surface of the substrate; forming a first barrier wall on the upper surface of the substrate, wherein the first barrier wall covers a lateral surface of the first semiconductor die and protrudes from an upper surface of the first semiconductor die; dispensing a first fluid material on the upper surface of the first semiconductor die, wherein the first barrier wall prevents the first fluid material from flowing across it; and curing the first fluid material to form a back side metallization (BSM) layer.

According to another aspect of the present application, a semiconductor package is provided. The semiconductor package may include: a substrate; a semiconductor die stack mounted on an upper surface of the substrate, wherein the semiconductor die stack includes a first semiconductor die; a first barrier wall formed on the upper surface of the substrate, wherein the first barrier wall covers a lateral surface of the first semiconductor die and protrudes from an upper surface of the first semiconductor die; and a back side metallization (BSM) layer formed on the upper surface of the first semiconductor die, wherein the BSM layer is at least partially enclosed with the first barrier wall.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view of a semiconductor package having a semiconductor die stack.

FIG. 1B is a microscopic image illustrating a back side metallization (BSM) layer of a semiconductor package.

FIGS. 2A to 2K are cross-sectional or top views illustrating various steps of a method for forming a semiconductor package according to an embodiment of the present application.

FIGS. 3A to 3C are cross-sectional views illustrating various steps of a method for forming a semiconductor package according to another embodiment of the present application.

FIGS. 4A to 4C are cross-sectional illustrating various steps of a method for forming a semiconductor package according to another embodiment of the present application.

FIG. 5A is a cross-sectional view illustrating a semiconductor package according to an embodiment of the present application.

FIG. 5B illustrates an enlarged view of a portion of the semiconductor package shown in FIG. 5A.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

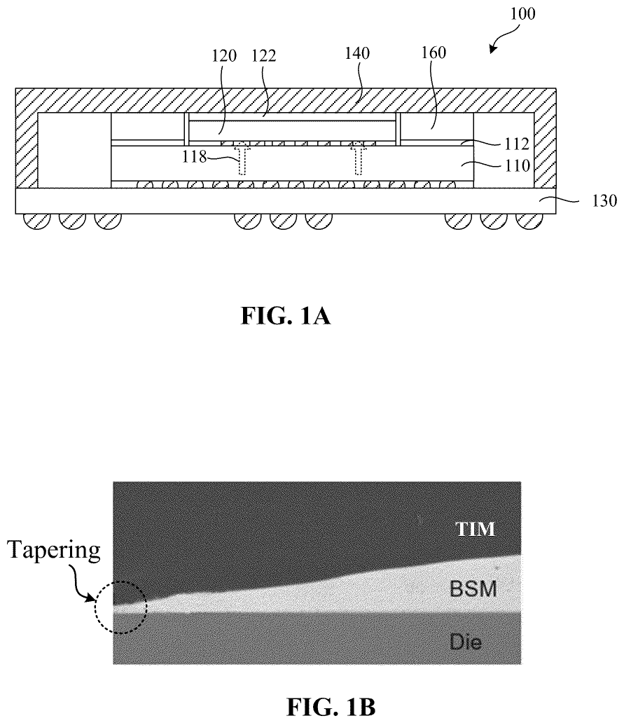

FIG. 1A is a cross-sectional view of a semiconductor package 100 having a semiconductor die stack. Specifically, the semiconductor package 100 includes a first semiconductor die 110 mounted to a substrate 130, and a second semiconductor die 120 stacked above the first semiconductor die 110. In order to dissipate heat generated by the semiconductor package 100 during operation, the first semiconductor die 110 is thermally coupled to a heat spreader 140 via a thermal interface material (TIM) layer 112 and a metal support 160, and the second semiconductor die 120 is also thermally coupled to the heat spreader 140 via another TIM layer 122, such that the heat generated by the first semiconductor die 110 and the second semiconductor die 120 can be transferred to the heat spreader 140 and further to the external environment. However, as shown in FIG. 1A, the second semiconductor die 120 which is used as a pathway for the heat 118 generated by the first semiconductor die 110 may block dissipation of the heat 118 because the material (e.g., silicon) of the second semiconductor die 120 may not have an ideal thermal conductivity. Thus, the performance of the semiconductor package 100 may be negatively impacted due to the poor heat dissipation.

The TIM layer 112 and the TIM layer 122 may be made of a metal material having a high thermal conductivity. However, metal TIM generally requires a back side metallization (BSM) layer formed on the semiconductor die (for example, the first semiconductor die 110 mounted to the substrate 130 or the second semiconductor die 120) to improve bonding performance. In order to apply a laser assist bonding (LAB) method for flip-chip soldering, a dispensing technique, such as an inkjet printing technique, is usually employed to form the BSM layer on the semiconductor die. However, as shown in FIG. 1B, inventors of the present applicant found that the BSM layer may have a tapering shape in its peripheral regions, which may be caused by a flow property of the material (e.g., an ink composition) used to form the BSM layer. As a result, voids or delamination may occur between the metal TIM layer and the BSM layer and/or between the BSM layer and the semiconductor die, reducing the heat dissipation capacity of the semiconductor package. Further, the inventors of the present applicant found that the BSM layer may be consumed after soldering with the metal TIM layer, and thus more delamination may be induced between the BSM layer and the semiconductor die.

To address at least one of the above problems, a method for forming a semiconductor package is provided. In the method, a semiconductor die stack including a first semiconductor die and a second semiconductor die mounted on the first semiconductor die is provided. After the semiconductor die stack is mounted on an upper surface of a substrate, a first barrier wall is formed on the upper surface of the substrate. The first barrier wall covers a lateral surface of the first semiconductor die and protrudes from an upper surface of the first semiconductor die. The first barrier wall can prevent a fluid material used for forming a BSM layer from flowing across it, such that the BSM layer may have a uniform thickness. Thus, voids or delamination between the BSM layer and the first semiconductor die can be reduced, and a heat dissipation capacity of the semiconductor package can be improved.

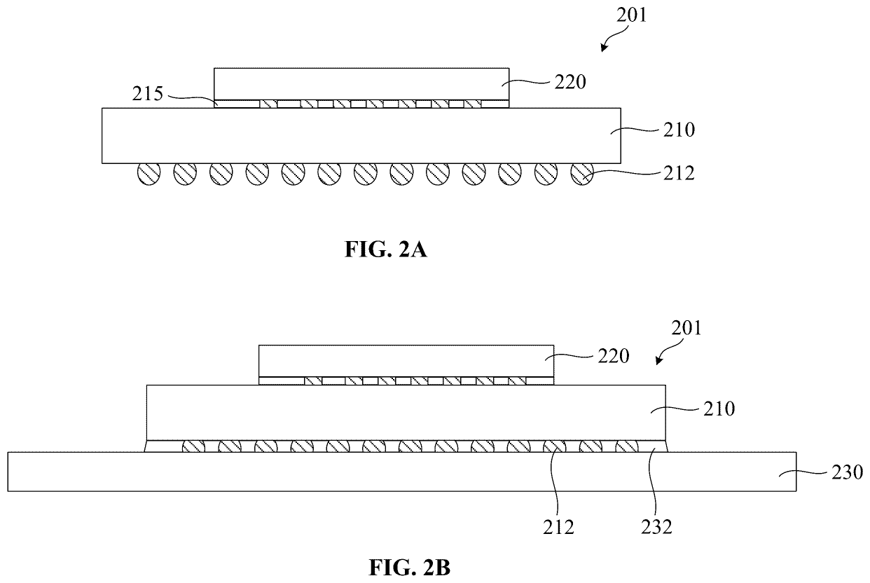

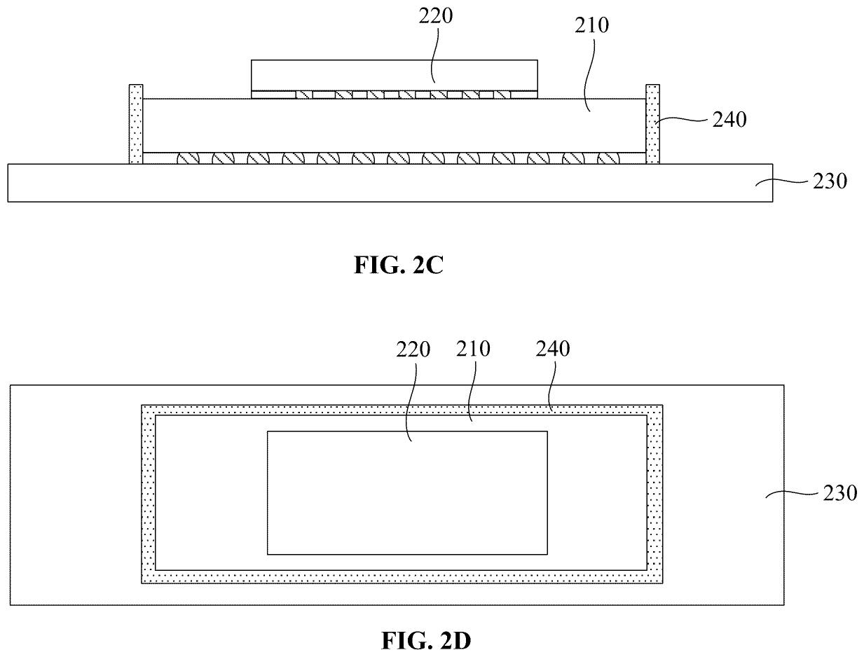

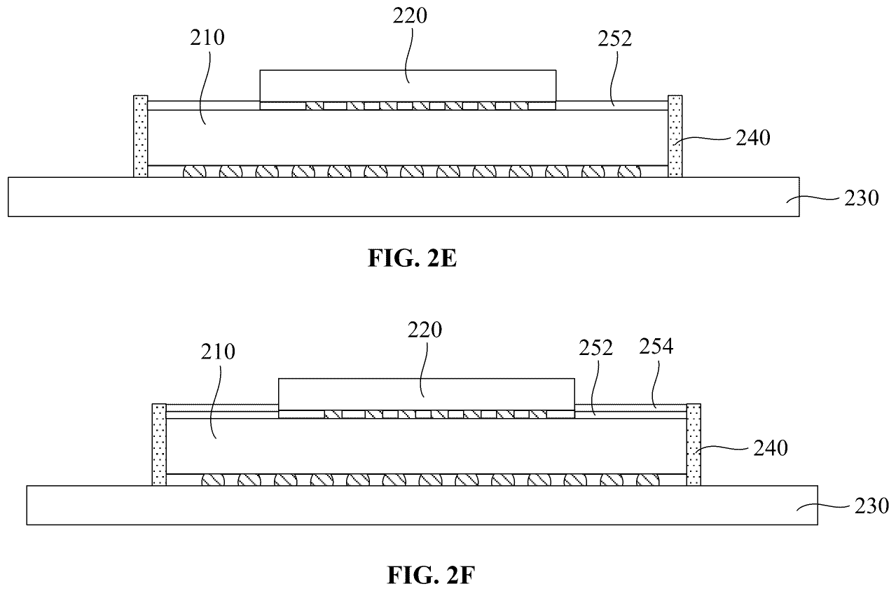

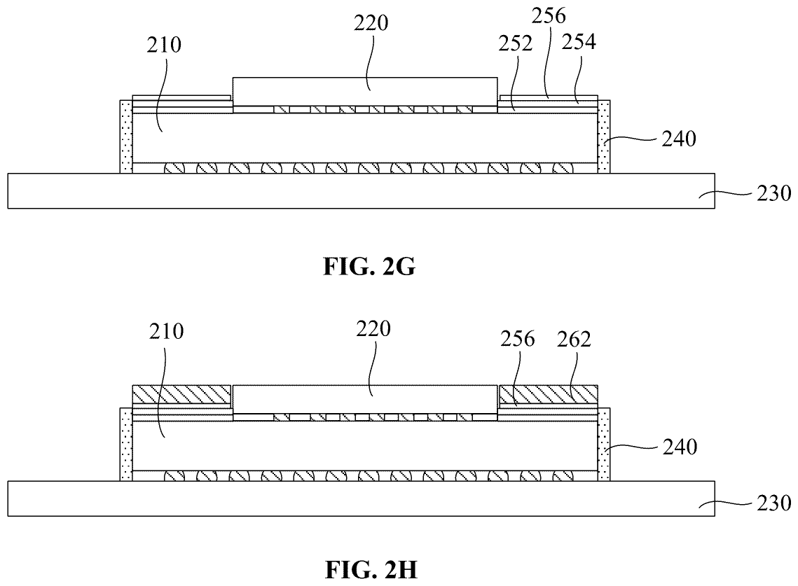

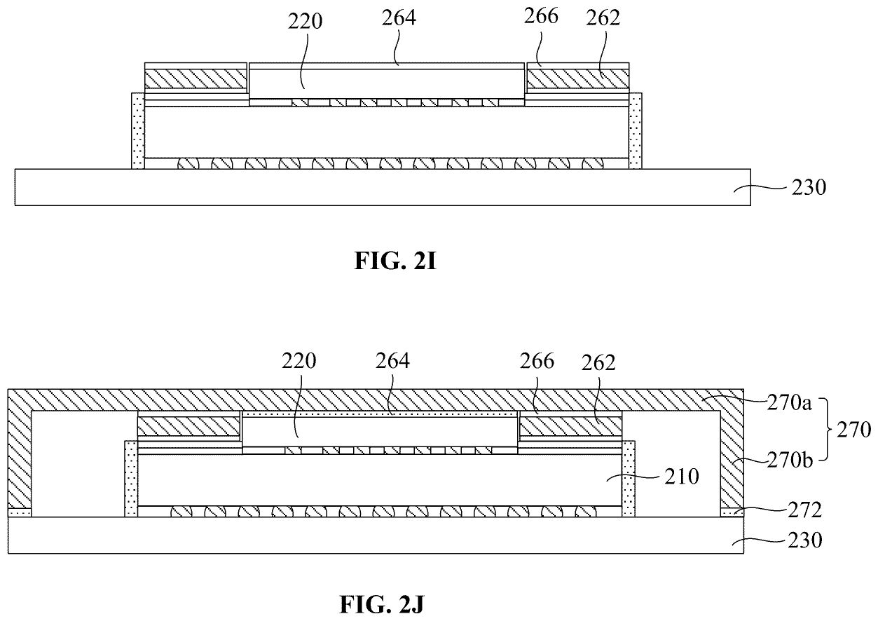

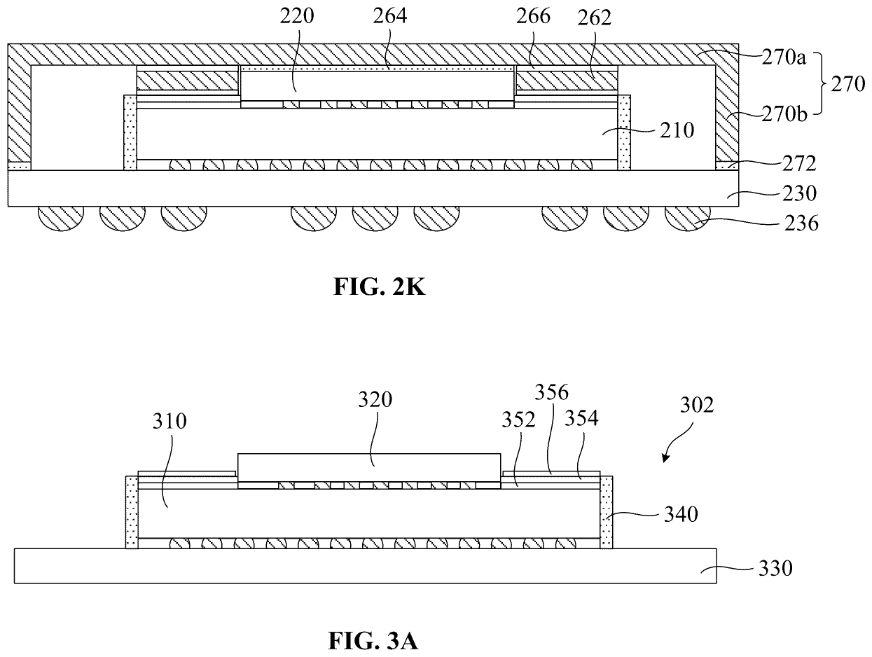

Referring to FIGS. 2A to 2K, various steps of a method for forming a semiconductor package are illustrated according to an embodiment of the present application. In the following, the method will be described with references to FIGS. 2A to 2K in more details.

Referring to FIG. 2A, a semiconductor die stack 201 is provided. The semiconductor die stack 201 may include a first semiconductor die 210 and a second semiconductor die 220.

The first semiconductor die 210 and/or the second semiconductor die 220 may include any of a logic chip, a microcontroller, a microprocessor, a network processor, a power management processor, an audio processor, a video processor, a digital signal processor (DSP), an application specific integrated circuit (ASIC), a radio frequency circuit, a wireless baseband system on chip (SoC) processor, a sensor, a memory controller, or a memory device. In a specific example, the first semiconductor die 210 may be a logic chip and the second semiconductor die 220 may be a memory chip. However, the present application is not limited to the above examples. In some other embodiments, there may be more than one semiconductor die vertically bonded on the first semiconductor die. In some embodiments, each of the first semiconductor die 210 and the second semiconductor die 220 may have a lower surface and an upper surface. In some embodiments, the lower surface may be an active surface on which a surface fabrication process can be implemented to form various types of semiconductor devices. The upper surface may serve as a support surface to which another electronic component may be attached. That is, the second semiconductor die 220 is flip-chip stacked on an upper surface of the first semiconductor die 210. In the example shown in FIG. 2A, the second semiconductor die 220 covers a central area, but exposes a peripheral area of the upper surface of the first semiconductor die 210. However, the present application is not limited to this example. In other embodiments, the second semiconductor die 220 is stacked on other positions of the upper surface of the first semiconductor die 210, but exposes at least a portion of the upper surface of the first semiconductor die 210 for heat dissipation.

As shown in FIG. 2A, the first semiconductor die 210 and the second semiconductor die 220 are bonded together by an interconnection layer 215. For example, the second semiconductor die 220 may be mounted on the upper surface of the first semiconductor die 210 by hybrid bonding. The interconnection layer 215 may include a dielectric material and conductive interconnect structures extending through the dielectric material and between the first semiconductor die 210 and the second semiconductor die 220. For example, the conductive interconnect structures may include copper posts, and electrically couple with through silicon vias (TSVs) formed in the first semiconductor die 210. However, the present application is not limited to the above examples. In other embodiments, the interconnection layer 215 may include a ball grid array (BGA) or other suitable interconnection structures. In addition, the first semiconductor die 210 may include a plurality of conductive bumps 212 formed on its lower surface. In the example shown in FIG. 2A, the conductive bumps 212 are illustrated as solder bumps, but the present application is not limited thereto. In some other embodiments, the conductive bumps 212 may include conductive pillars, or copper balls. The conductive bumps 212 may be used for electrically connecting the semiconductor die stack 201 to an external device or substrate.

Referring to FIG. 2B, a substrate 230 is provided, and the semiconductor die stack 201 is mounted on an upper surface of the substrate 230.

The substrate 230 can support the semiconductor die stack 201 and further connect the semiconductor die stack 201 with other electronic components. By way of example, the substrate 230 may be a printed circuit board. However, the substrate 230 is not limited thereto. In other examples, the substrate 230 may be a semiconductor substrate, a laminate interposer, a strip interposer, a leadframe, or other suitable substrates. In accordance with the scope of the present application, the substrate 230 may include any structure on or in which integrated circuit systems are fabricated. For example, the substrate 230 may include one or more insulating or passivation layers, one or more conductive vias formed through the insulating layers, and one or more conductive layers formed over or between the insulating layers. For example, redistribution structures (RDSs) may be formed in the substrate 230, which include a plurality of upper conductive patterns on the upper surface of the substrate 230, a plurality of lower conductive patterns on the lower surface of the substrate 230, and a plurality of conductive vias electrically connecting at least one of the upper conductive patterns with at least one of the lower conductive patterns.

In some embodiments, the semiconductor die stack 201 may be positioned over the substrate 230 using a pick and place operation with the conductive bumps 212 of the first semiconductor die 210 oriented toward the substrate 230. The conductive bumps 212 may contact the upper conductive pattern of the RDS in the substrate 230. In some embodiments, a laser assisted bonding (LAB) process may be performed to mount the semiconductor die stack 201 on the substrate 230 via the conductive bumps 212. However, the present application is not limited to the above embodiments. In some other embodiments, a mass reflow process or a thermocompression bonding process may be performed to mount the semiconductor die stack 201 onto the upper surface of the substrate 230. In some embodiments, an underfill encapsulant 232 may be formed between the first semiconductor die 210 and the substrate 230. The underfill encapsulant 232 may include a polymer composite material, such as epoxy resin, epoxy acrylate, or polymer with or without a filler. The underfill encapsulant 232 may provide mechanical support to the conductive bumps 212, helping to mitigate the risk of crack or delamination due to differential thermal expansion between the first semiconductor die 210 and the substrate 230.

Referring to FIG. 2C, a first barrier wall 240 is formed on the upper surface of the substrate 230. The first barrier wall 240 may cover a lateral surface of the first semiconductor die 210 and protrude from the upper surface of the first semiconductor die 210.

In some embodiments, a directly dispensing apparatus may be used to dispensing a fluid composition including a photocurable material and/or a thermosetting material on the upper surface of the substrate 230 and around the underfill encapsulant 232 and the first semiconductor die 210, and then the fluid composition may be cured to form the first barrier wall 240. Depending on properties of the fluid composition, the fluid composition may be cured by an ultraviolet (UV), infrared (IR) or near infrared (NIR) radiation, or under a predetermined temperature for a predetermined period.

For example, an inkjet printing apparatus may be used to form the first barrier wall 240 on the substrate 230. The inkjet printing apparatus may include a dispensing nozzle configured for dispensing an ink composition and a light source configured for irradiating a light beam with a predetermined intensity. Specifically, the dispensing nozzle of the inkjet printing apparatus is controlled to produce droplets of the ink composition in the order of several to several tens of micrometers in diameter, which will be projected towards the substrate 230. By moving the substrate 230 or the dispensing nozzle relative to each other, the droplets can be dispensed onto the upper surface of the substrate 230 at a location where the first barrier wall 240 is to be formed. The light source of the inkjet printing apparatus may be controlled to irradiate a light beam to cure the material in the droplets. By continuously moving the substrate 230 or the dispensing nozzle of the inkjet printing apparatus, dispensing the droplets of the ink composition and curing the droplets with light irradiation, the first barrier wall 240 can be formed on the upper surface of the substrate 230. In another example, an aerosol printing apparatus may be used to form the first barrier wall 240 on the substrate 230. The aerosol printing apparatus can atomize the fluid composition via ultrasonic or pneumatic means, so as to produce droplets on the order of one to more micrometers in diameter. The droplets may be entrained in a gas stream and delivered to a print head. At the print head, a sheath gas flow may be introduced to focus the droplets into a tightly collimated beam of material. Then, the combined gas streams may fly out of the print head through a converging nozzle that compresses the aerosol stream to particles or droplets with a small diameter. The jet of droplets may fly out of the print head at a high velocity and impinge upon the upper surface of the substrate 230, and the droplets can be continuously dispensed on the upper surface of the substrate 230 by moving the print head of the aerosol printing apparatus. Afterwards, the fluid composition may be cured to form the first barrier wall 240. As the inkjet printing apparatus and the aerosol printing apparatus can accurately control the position and/or the dispensing time of the droplets, the first barrier wall 240 can be directly formed at a desired area with a desired shape without any mask, or any photolithography process. It could be understood that the present application is not limited to the above embodiments, and the first barrier wall 240 can be formed by any other suitable printing apparatus, such as an electrohydrodynamic (EHD) printing apparatus, a nozzle printing apparatus, or a spray coating apparatus.

In some embodiments, the fluid composition for forming the first barrier wall 240 may include an epoxy compound. The epoxy compound may include various photosensitive resin compositions or various heat curable resin compositions. In some embodiments, the first barrier wall 240 may include other dielectric/insulating materials having sufficient properties such as hardness, heat resistance, chemical resistance, and/or electrical insulation reliability. In some embodiments, the first barrier wall 240 may include solder resist, paste, UV curable material, a fluid including a metal precursor, and/or other materials with high viscosity that can be coated by inkjet printing, aerosol printing, EHD printing, nozzle printing, or spray coating techniques.

FIG. 2D illustrates a top view of the structure shown in FIG. 2C. In some embodiments, as shown in FIG. 2D, the first barrier wall 240 may have a width ranging from micrometers to millimeters, and may be formed along four edges of the first semiconductor die 210. Thus, the first barrier wall 240 forms a closed ring having a rectangular geometric shaped footprints on the upper surface of the substrate 230. The first barrier wall 240 may have a rectangular cross section, a trapezoidal cross section, or other polygonal-shaped cross sections. It could be understood that the present application is not limited to the example shown in FIG. 2D. In other embodiments, depending on a shape of the first semiconductor die 210, the first barrier wall 240 may form a closed or partially closed ring having a square, hexagonal, or any other geometric shaped footprints on the upper surface of the substrate 230.

In some embodiments, a second barrier wall may be formed on the upper surface of the first semiconductor die 210. The second barrier wall may cover a lateral surface of the second semiconductor die 220. Thus, a fluid material dispensed on the upper surface of the first semiconductor die 210 in subsequent steps can be limited between the first barrier wall 240 and the second barrier wall. In some embodiments, the second barrier wall may also protrude from the upper surface of the first semiconductor die 210 to prevent any fluid material dispensed on the upper surface of the second semiconductor die 210 from flowing across it.

Referring to FIG. 2E, a first fluid material is dispensed on the upper surface of the first semiconductor die 210, and then the first fluid material is cured to form a back side metallization (BSM) layer 252.

Specifically, the first fluid material may be dispensed on the upper surface of the first semiconductor die 210 by using an inkjet printing apparatus, an aerosol printing apparatus, an EHD printing apparatus, a nozzle printing apparatus, or a spray coating apparatus. As the first barrier wall 240 covers the lateral surface of the first semiconductor die 210 and protrudes from the upper surface of the first semiconductor die 210, the first barrier wall 240 can prevent the first fluid material from flowing across it. After the first fluid material is cured by an UV, IR or NIR radiation, or under a predetermined temperature for a predetermined period, the BSM layer 252 can be formed with a generally uniform thickness. That is, the BSM layer 252 doesn't have a tapering shape in its peripheral regions, and can assist a TIM layer formed in a subsequent process in adhering to the first semiconductor die 210. In some embodiments, the BSM layer 252 may include one or more materials selected from a group consisting of silver, copper, gold, or aluminum. However, the BSM layer 252 is not limited to the above materials, and may include other suitable material.

Referring to FIG. 2F, a second fluid material is dispensed on the BSM layer 252, and then the second fluid material is cured to form a barrier layer 254 on the BSM layer 252.

Specifically, the second fluid material may be dispensed on the BSM layer 252 by using an inkjet printing apparatus, an aerosol printing apparatus, an EHD printing apparatus, a nozzle printing apparatus, or a spray coating apparatus. The first barrier wall 240 may have a sufficient height to prevent the second fluid material from flowing across it. After the second fluid material is cured by an UV, IR or NIR radiation, or under a predetermined temperature for a predetermined period, the barrier layer 254 can be formed on the BSM layer 252. The barrier layer 254 can reduce consumption of the BSM layer 252 during a subsequent soldering process. In some embodiments, the barrier layer 254 may include one or more materials selected from a group consisting of nickel, titanium, silicon oxide, aluminum oxide, graphene, boron nitride or molybdenum sulfide. However, the barrier layer 254 is not limited to the above materials, and may include other suitable material.

In the above embodiment, the second fluid material is dispensed after the first fluid material is cured. However, the present application is not limited thereto. In other embodiments, the second fluid material may be dispensed on the first fluid material, and then the first fluid material and the second fluid material are cured simultaneously.

Referring to FIG. 2G, a first thermal interface material (TIM) layer 256 is disposed on the barrier layer 254.

In some embodiments, the first TIM layer 256 may include indium, or an indium silver (InAg) alloy. However, the first TIM layer 256 is not limited to the above materials, and may include other materials with a high thermal conductivity. In some embodiments, the first TIM layer 256 may be pre-formed, and can be attached to the barrier layer 254. That is, the first TIM layer 256 will not directly contact with the BSM layer 252. In an example, a first soldering flux layer may be formed on a lower surface of the first TIM layer 256, and a second soldering flux layer may be formed on an upper surface of the first TIM layer 256. Thus, the first TIM layer 256 can be attached to the barrier layer 254 via the first soldering flux layer, and another component can be attached to the TIM layer 256 via the second soldering flux layer. The first soldering flux layer and the second soldering flux layer can facilitate reflowing of the first TIM layer 256 in subsequent processes. However, the present application is not limited to the above embodiment, in some other embodiments, the first TIM layer 256 may be formed on the barrier layer 254 by using sputtering, electrolytic plating, electroless plating, or other suitable deposition process.

Referring to FIG. 2H, a heat transfer component 262 is disposed on the first TIM layer 256.

In some embodiments, an upper surface of the heat transfer component 262 is substantially flush or coplanar with the upper surface of the second semiconductor die 220, so as to facilitate attachment of a heat spreader in a subsequent process. The heat transfer component 262 can serve as a pathway to the heat spreader for the heat generated by the first semiconductor die 210 during operation. In some embodiments, the heat transfer component 262 may fully surround the second semiconductor die 220. In some embodiments, the heat transfer component 262 may partially surround the second semiconductor die 220. In some embodiments, the heat transfer component 262 may include multiple sub-blocks, such as four sub-blocks respectively disposed adjacent to the four lateral sides of the second semiconductor die 220.

In some embodiments, the heat transfer component 262 may include copper, aluminum, nickel-plated copper, nickel-plated aluminum, or other materials with a high thermal conductivity. In an example, a first surface finish layer may be formed on a lower surface of the heat transfer component 262, and a second surface finish layer may be formed on an upper surface of the heat transfer component 262. The first and second surface finish layers can prevent oxidation of the heat transfer component 262. In this example, the heat transfer component 262 is attached on the first TIM layer 256 via the first surface finish layer. Thus, the first surface finish layer may include a suitable material to wet the first TIM layer 256. In some embodiments, the first and second surface finish layers may include gold. In some embodiments, the first and second surface finish layers may include other materials such as silver or indium.

In some embodiments, after the heat transfer component 262 is disposed on the first TIM layer 256, the first TIM layer 256 is reflowed to solder the first TIM layer 256 and the barrier layer 254 together, and solder the first TIM layer 256 and the heat transfer component 262 together, such that the heat transfer component 262 is firmly attached on the upper surface of the first semiconductor die 210. Specifically, the first TIM layer 256 may be heated above its melting point, such that the soldering flux between the first TIM layer 256 and the barrier layer 254 may escape into the environment, and the first TIM layer 256 and the barrier layer 254 may react to form an intermetallic compound (IMC). The IMC can enhance the adhesion between the first TIM layer 256 and the barrier layer 254. Similarly, when the first TIM layer 256 is heated above its melting point, the soldering flux between the first TIM layer 256 and the heat transfer component 262 may escape into the environment, and the first TIM layer 256 and the heat transfer component 262 may react to form another IMC to enhance the adhesion between the first TIM layer 256 and the heat transfer component 262.

Referring to FIG. 2I, a second TIM layer 264 is disposed on the second semiconductor die 220, and a third TIM layer 266 is disposed on the heat transfer component 262.

The second TIM layer 264 and the third TIM layer 266 may be pre-formed, and can be attached to the second semiconductor die 220 and the heat transfer component 262, respectively. The second TIM layer 264 and/or the third TIM layer 266 may include a material same as or different from the first TIM layer 256, for example, indium, or an InAg alloy. In some embodiments, soldering flux may be formed on lower surfaces and upper surfaces of the second TIM layer 264 and/or the third TIM layer 266 to facilitate subsequent soldering processes. In some other embodiments, the second TIM layer 264 and/or the third TIM layer 266 may be formed on the second semiconductor die 220 and/or the heat transfer component 262 by using sputtering, electrolytic plating, electroless plating, or other suitable deposition process.

Referring to FIG. 2J, a heat spreader 270 is provided. The heat spreader 270 may include a lid 270a and a first lateral portion 270b extending downwards from the lid 270a. An adhesive layer 272 may be formed on the upper surface of the substrate 230, and then the first lateral portion 270b of the heat spreader 270 is attached on the upper surface of the substrate 230 via the adhesive layer 272 with the lid 270a contacting with the second TIM layer 264 and the third TIM layer 266.

In some embodiments, the adhesive layer 272 may include a solder material and is dispensed on the upper surface of the substrate 230. In some embodiments, the adhesive layer 272 may include a conductive or non-conductive film, a UV film, an instant adhesive, a thermosetting adhesive, or any other suitable adhesive materials. In some embodiments, the heat spreader 270 may include copper, aluminum, nickel or other metal materials. However, the heat spreader 270 is not limited to the above materials, and may include other materials with a high thermal conductivity. In order to facilitate the coupling between the heat spreader 270 and the second TIM layer 264 and the third TIM layer 266, a surface finish layer may be formed on an underside of the lid 270a.

After the first lateral portion 270b of the heat spreader 270 is attached on the upper surface of the substrate 230 via the adhesive layer 272, the second TIM layer 264 and the third TIM layer 266 may be reflowed, such that the lid 270a of the heat spreader 270 can be attached on the second semiconductor die 220 and the heat transfer component 262. Consequently, the first semiconductor die 210 is thermally coupled to the lid 270a of the heat spreader 270 via the BSM layer 252, the barrier layer 254, the first TIM layer 256, the heat transfer component 262 and the third TIM layer 266; and the second semiconductor die 220 is thermally coupled to the lid 270a of the heat spreader 270 via the second TIM layer 264. Thus, the heat dissipation capacity of the semiconductor package can be improved.

Afterwards, referring to FIG. 2K, a plurality of conductive bumps 236 may be formed on the lower surface of the substrate 230.

For example, the conductive bumps 236 may be formed on the conductive patterns on the lower surface of the substrate 230, so as to electrically couple with the first semiconductor die 210 and/or the second semiconductor die 220. In the example shown in FIG. 2K, the conductive bumps 236 are illustrated as solder bumps, but the present application is not limited thereto. In some other embodiments, the conductive bumps 236 may include conductive pillars, or copper balls. In a case where the semiconductor package is mounted on an external device or substrate such as a printed circuit board (PCB), the conductive bumps 212 may be used for electrically connecting the semiconductor package to the external device or substrate.

In the above example shown in FIGS. 2A to 2K, the first TIM layer 256 is first reflowed after the heat transfer component 262 is disposed on the first TIM layer 256, and, afterwards, the second TIM layer 264 and the third TIM layer 266 are reflowed after the first lateral portion 270b of the heat spreader 270 is attached on the upper surface of the substrate 230. However, the present application is not limited thereto. In some other embodiments, the first TIM layer 256, the second TIM layer 264 and the third TIM layer 266 may be reflowed simultaneously, for example, after the first lateral portion 270b of the heat spreader 270 is attached on the upper surface of the substrate 230.

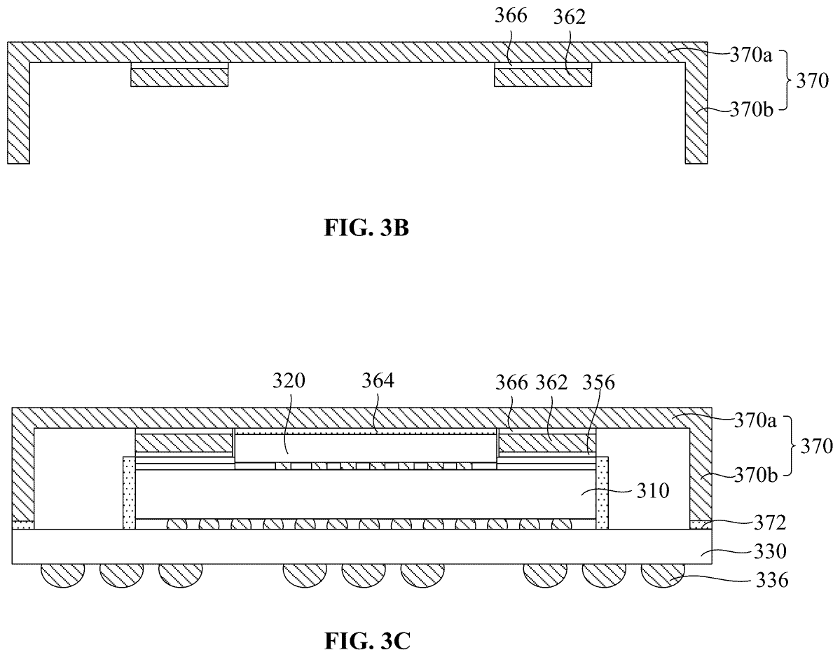

Referring to FIGS. 3A to 3C, various steps of a method for forming a semiconductor package are illustrated according to another embodiment of the present application.

Referring to FIG. 3A, a package 302 is provided. The package 302 may include a substrate 330, a first semiconductor die 310 mounted on an upper surface of the substrate 330 and a second semiconductor die 320 mounted on an upper surface of the first semiconductor die 310. A first barrier wall 340 is formed on the upper surface of the substrate 330, and the first barrier wall 340 covers a lateral surface of the first semiconductor die 310 and protrudes from the upper surface of the first semiconductor die 310. A BSM layer 352 is formed on the upper surface of the first semiconductor die 310 and is at least partially enclosed with the first barrier wall 340. Further, a barrier layer 354 is formed on the BSM layer 352, and a first TIM layer 356 is formed on the barrier layer 354. The package 302 shown in FIG. 3A is similar to the structure shown in FIG. 2G, and will not be elaborated herein.

Referring to FIG. 3B, a heat spreader 370 is provided. The heat spreader 370 may include a lid 370a and a first lateral portion 370b extending downwards from the lid 370a. Then, a heat transfer component 362 may be attached on a lower surface of the lid 370a of the heat spreader 370. For example, the heat transfer component 362 may be attached onto the lower surface of the lid 370a via a third TIM layer 366. However, the present application is not limited thereto. In some other embodiments, the heat transfer component 362 may be attached onto the lower surface of the lid 370a via another attachment method such as welding, brazing, soldering or pressing.

Afterwards, referring to FIG. 3C, a second TIM layer 364 is disposed on the second semiconductor die 320. Then, an adhesive layer 372 may be formed on the upper surface of the substrate 330, and the first lateral portion 370b of the heat spreader 370 is attached on the upper surface of the substrate 330 via the adhesive layer 372 with the heat transfer component 362 contacting with the first TIM layer 356 and the lid 370a contacting with the second TIM layer 364. Then, the first TIM layer 356 and the second TIM layer 364 are reflowed to attach the heat transfer component 362 on the first semiconductor die 310 and attach the lid 370a of the heat spreader 370 on the second semiconductor die 320. At last, a plurality of conductive bumps 336 may be formed on the lower surface of the substrate 330.

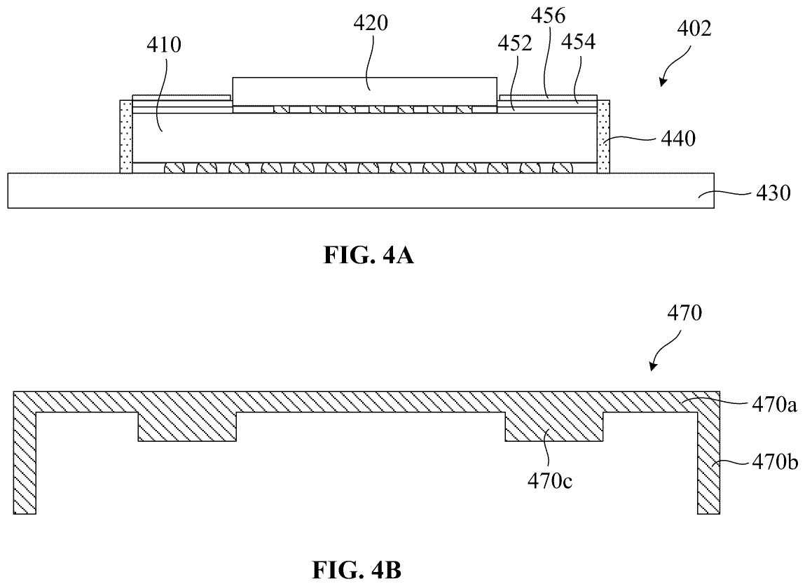

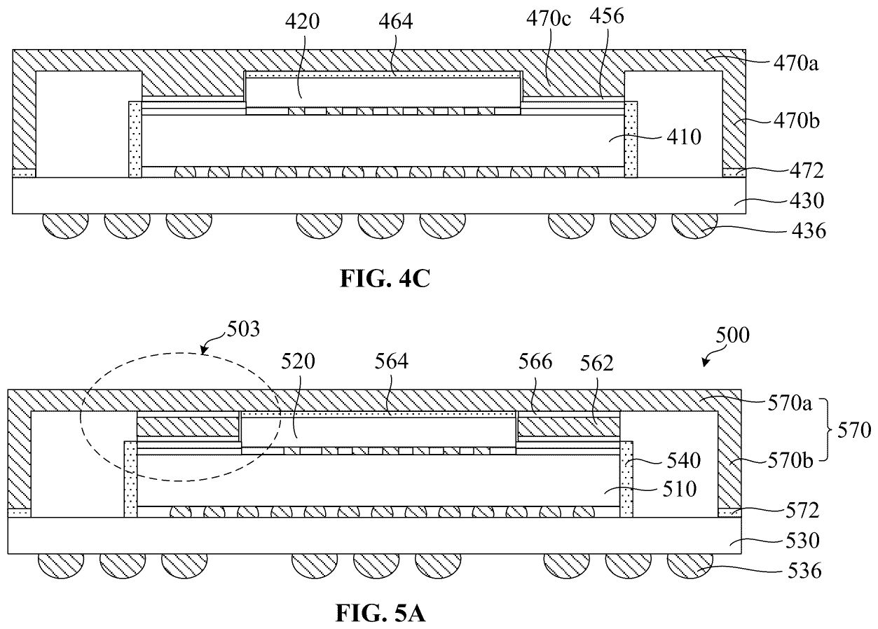

Referring to FIGS. 4A to 4C, various steps of a method for forming a semiconductor package are illustrated according to another embodiment of the present application.

Referring to FIG. 4A, a package 402 is provided. The package 402 may include a substrate 430, a first semiconductor die 410 mounted on an upper surface of the substrate 430 and a second semiconductor die 420 mounted on an upper surface of the first semiconductor die 410. A first barrier wall 440 is formed on the upper surface of the substrate 430, and the first barrier wall 440 covers a lateral surface of the first semiconductor die 410 and protrudes from the upper surface of the first semiconductor die 410. A BSM layer 452 is formed on the upper surface of the first semiconductor die 410 and is at least partially enclosed with the first barrier wall 440. Further, a barrier layer 454 is formed on the BSM layer 452, and a first TIM layer 456 is formed on the barrier layer 454. The package 402 shown in FIG. 4A is similar to the structure shown in FIG. 2G, and will not be elaborated herein.

Referring to FIG. 4B, a heat spreader 470 is provided. The heat spreader 470 may include a lid 470a and a first lateral portion 470b extending downwards from the lid 470a. Different from the heat spreader 370 shown in FIG. 3B, the heat spreader 470 further includes a second lateral portion 470c extending downwards from the lid 470a. Compared to the first lateral portion 470b, the second lateral portion 470c is closer to a central area of the lid 470a. In some embodiments, the lid 470a, the first lateral portion 470b and the second lateral portion 470c are integrally formed as a single piece.

Afterwards, referring to FIG. 4C, a second TIM layer 464 is disposed on the second semiconductor die 420. Then, an adhesive layer 472 may be formed on the upper surface of the substrate 430, and the first lateral portion 470b of the heat spreader 470 is attached on the upper surface of the substrate 430 via the adhesive layer 472 with the second lateral portion 470c of the heat spreader 470 contacting with the first TIM layer 456 and the lid 470a contacting with the second TIM layer 464. Then, the first TIM layer 456 and the second TIM layer 464 are reflowed to attach the second lateral portion 470c of the heat spreader 470 on the first semiconductor die 410 and attach the lid 470a of the heat spreader 470 on the second semiconductor die 420. At last, a plurality of conductive bumps 436 may be formed on the lower surface of the substrate 430.

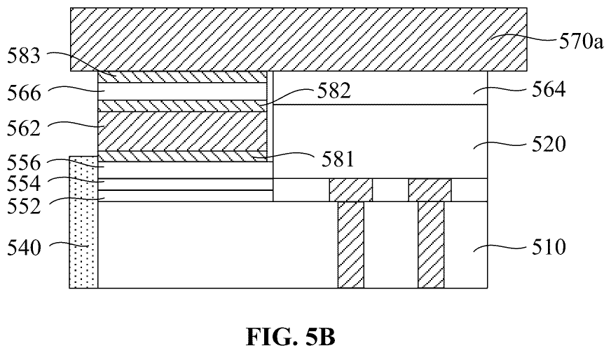

According to another aspect of the present application, a semiconductor package is provided. Referring to FIG. 5A and FIG. 5B, FIG. 5A illustrates a cross-sectional view of a semiconductor package 500 according to an embodiment of the present application, and FIG. 5B illustrates an enlarged view of a portion 503 of the semiconductor package 500 shown in FIG. 5A.

Referring both FIG. 5A and FIG. 5B, the semiconductor package 500 may include a substrate 530, a first semiconductor die 510 mounted on an upper surface of the substrate 530, and a second semiconductor die 520 mounted on an upper surface of the first semiconductor die 510, for example, by hybrid bonding. A first barrier wall 540 is formed on the upper surface of the substrate 530, and the first barrier wall 540 covers a lateral surface of the first semiconductor die 510 and protrudes from the upper surface of the first semiconductor die 510. A BSM layer 552 is formed on the upper surface of the first semiconductor die 510 and is at least partially enclosed with the first barrier wall 540. In some embodiments, a barrier layer 554 is formed on the BSM layer 552, and the barrier layer 554 is at least partially enclosed with the first barrier wall 540. The BSM layer 552 may include silver, copper, gold or aluminum, and the barrier layer 554 may include nickel, titanium, silicon oxide, aluminum oxide, graphene, boron nitride or molybdenum sulfide.

In some embodiments, a first TIM layer 556 is attached on the barrier layer 554, a heat transfer component 562 is attached on the first TIM layer 556, and a third TIM layer 566 is attached on the heat transfer component 562. In the example shown in FIG. 5B, a first surface finish layer 581 may be formed on a lower surface of the heat transfer component 562 to improve interface characteristics between the heat transfer component 562 and the first TIM layer 556, and a second surface finish layer 582 may be formed on an upper surface of the heat transfer component 562 to improve interface characteristics between the heat transfer component 562 and the third TIM layer 566.

In some embodiments, the semiconductor package 500 may further include a heat spreader 570 having a lid 570a and a first lateral portion 570b extending downwards from the lid 570a. The first lateral portion 570b of the heat spreader 570 may be attached on the upper surface of the substrate 530 via an adhesive layer 572. The lid 570a of the heat spreader 570 is attached to the second semiconductor die 520 via a second TIM layer 564 and attached to the heat transfer component 562 via a third TIM layer 566. In the example shown in FIG. 5B, a third surface finish layer 583 may be formed on a lower surface of the lid 570a of the heat spreader 570 to improve interface characteristics between the lid 570a of the heat spreader 570 and the third TIM layer 566.

The semiconductor package 500 may be formed by the method described above with reference to FIGS. 2A to 2K or the method described above with reference to FIGS. 3A to 3C. Thus, more details about the semiconductor package 500 may be referred to the disclosure and drawings about the method disclosed above, and will not will not be elaborated herein.

While the semiconductor package of the present application is described with reference to FIGS. 5A and 5B, it will be understood by those skilled in the art that modifications and adaptations to the semiconductor package may be made without departing from the scope of the present invention. For example, in some other embodiments, a second barrier wall may be formed on the upper surface of the first semiconductor die. The second barrier wall may cover a lateral surface of the second semiconductor die and protrude from the upper surface of the second semiconductor die. In some other embodiments, the heat spreader may further include a second lateral portion extending downwards from the lid. Thus, the second lateral portion of the heat spreader can be directly attached on the first semiconductor die via the first TIM layer. That is, the heat transfer component can be omitted in these embodiments. For example, the semiconductor package of these embodiments may be formed by the method described above with reference to FIGS. 4A to 4C.

The discussion herein included numerous illustrative figures that showed various portions of a semiconductor package and a method for making the same. For illustrative clarity, such figures did not show all aspects of each exemplary semiconductor package. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a substrate;
providing a semiconductor die stack comprising a first semiconductor die;
mounting the semiconductor die stack on an upper surface of the substrate;
forming a first barrier wall on the upper surface of the substrate, wherein the first barrier wall covers a lateral surface of the first semiconductor die and protrudes from an upper surface of the first semiconductor die;
dispensing a first fluid material on the upper surface of the first semiconductor die, wherein the first barrier wall prevents the first fluid material from flowing across it; and
curing the first fluid material to form a back side metallization (BSM) layer.

2. The method of claim 1, wherein providing the semiconductor die stack comprises:
providing the first semiconductor die; and
mounting a second semiconductor die on the upper surface of the first semiconductor die by hybrid bonding.

3. The method of claim 2, wherein before dispensing the first fluid material on the upper surface of the first semiconductor die, the method further comprises:
forming a second barrier wall on the upper surface of the first semiconductor die, wherein the second barrier wall covers a lateral surface of the second semiconductor die.

4. The method of claim 3, further comprising:
dispensing a second fluid material on the BSM layer, wherein the first barrier wall prevents the second fluid material from flowing across it; and
curing the second fluid material to form a barrier layer on the BSM layer.

5. The method of claim 4, further comprising:
forming an adhesive layer on the upper surface of the substrate;
providing a heat spreader comprising a lid and a first lateral portion extending downwards from the lid; and
attaching the first lateral portion of the heat spreader on the upper surface of the substrate via the adhesive layer.

6. The method of claim 5, further comprising:
disposing a first thermal interface material (TIM) layer on the barrier layer;
disposing a heat transfer component on the first TIM layer;
reflowing the first TIM layer to attach the heat transfer component on the first semiconductor die;
disposing a second TIM layer on the second semiconductor die;
disposing a third TIM layer on the heat transfer component;
disposing the heat spreader on the second semiconductor die with the lid contacting with the second TIM layer and the third TIM layer; and
reflowing the second TIM layer and the third TIM layer to attach the lid of the heat spreader on the second semiconductor die and the heat transfer component.

7. The method of claim 5, further comprising:
disposing a first thermal interface material (TIM) layer on the barrier layer;
disposing a heat transfer component on the first TIM layer;
disposing a second TIM layer on the second semiconductor die;
disposing a third TIM layer on the heat transfer component;
disposing the heat spreader on the second semiconductor die with the lid contacting with the second TIM layer and the third TIM layer; and
reflowing the first TIM layer, the second TIM layer and the third TIM layer to attach the heat transfer component on the first semiconductor die and attach the lid of the heat spreader on the second semiconductor die and the heat transfer component.

8. The method of claim 5, further comprising:
disposing a first thermal interface material (TIM) layer on the barrier layer;
attaching a heat transfer component on a lower surface of the lid of the heat spreader;
disposing a second TIM layer on the second semiconductor die;
disposing the heat spreader on the second semiconductor die with the heat transfer component contacting with the first TIM layer and the lid contacting with the second TIM layer; and
reflowing the first TIM layer and the second TIM layer to attach the heat transfer component on the first semiconductor die and attach the lid of the heat spreader on the second semiconductor die.

9. The method of any one of claim 6, wherein a first surface finish layer is formed on a lower surface of the heat transfer component and a second surface finish layer is formed on an upper surface of the heat transfer component.

10. The method of claim 5, wherein the heat spreader further comprises a second lateral portion extending downwards from the lid, and the method further comprises:
disposing a first thermal interface material (TIM) layer on the barrier layer;
disposing a second TIM layer on the second semiconductor die;
disposing the heat spreader on the second semiconductor die with the second lateral portion contacting with the first TIM layer and the lid contacting with the second TIM layer; and
reflowing the first TIM layer and the second TIM layer to attach the second lateral portion of the heat spreader on the first semiconductor die and attach the lid of the heat spreader on the second semiconductor die.

11. A semiconductor package, comprising:
a substrate;
a semiconductor die stack mounted on an upper surface of the substrate, wherein the semiconductor die stack comprises a first semiconductor die;
a first barrier wall formed on the upper surface of the substrate, wherein the first barrier wall covers a lateral surface of the first semiconductor die and protrudes from an upper surface of the first semiconductor die; and
a back side metallization (BSM) layer formed on the upper surface of the first semiconductor die, wherein the BSM layer is at least partially enclosed with the first barrier wall.

12. The semiconductor package of claim 11, wherein the semiconductor die stack further comprises a second semiconductor die mounted on the upper surface of the first semiconductor die by hybrid bonding.

13. The semiconductor package of claim 12, further comprises:
a second barrier wall formed on the upper surface of the first semiconductor die, wherein the second barrier wall covers a lateral surface of the second semiconductor die.

14. The semiconductor package of claim 13, further comprises:
a barrier layer formed on the BSM layer, wherein the barrier layer is at least partially enclosed with the first barrier wall.

15. The semiconductor package of claim 14, wherein the BSM layer comprises silver, copper, gold or aluminum, and the barrier layer comprises nickel, titanium, silicon oxide, aluminum oxide, graphene, boron nitride or molybdenum sulfide.

16. The semiconductor package of claim 14, further comprises:
an adhesive layer formed on the upper surface of the substrate; and
a heat spreader comprising a lid and a first lateral portion extending downwards from the lid, wherein the first lateral portion of the heat spreader is attached on the upper surface of the substrate via the adhesive layer.

17. The semiconductor package of claim 16, further comprises:
a first thermal interface material (TIM) layer attached on the barrier layer;
a heat transfer component attached on the first TIM layer;
a second TIM layer attached on the second semiconductor die; and
a third TIM layer attached on the heat transfer component, wherein the lid of the heat spreader is attached to the second semiconductor die and the heat transfer component via the second TIM layer and the third TIM layer, respectively.

18. The semiconductor package of claim 16, further comprises:
a first thermal interface material (TIM) layer attached on the barrier layer;
a second TIM layer attached on the second semiconductor die; and
a heat transfer component attached on a lower surface of the lid of the heat spreader, wherein the heat transfer component is also attached on the first semiconductor die via the first TIM layer, and the lid of the heat spreader is attached on the second semiconductor die via the second TIM layer.

19. The semiconductor package of claim 17, wherein a first surface finish layer is formed on a lower surface of the heat transfer component and a second surface finish layer is formed on an upper surface of the heat transfer component.

20. The semiconductor package of claim 16, wherein the heat spreader further comprises a second lateral portion extending downwards from the lid, and the semiconductor package further comprises:
a first thermal interface material (TIM) layer attached on the barrier layer; and
a second TIM layer attached on the second semiconductor die, wherein the second lateral portion of the heat spreader is attached on the first semiconductor die via the first TIM layer, and the lid of the heat spreader is attached on the second semiconductor die via the second TIM layer.
